(19) United States
(12) Patent Application Publication
(10) Pub. No.: US 2026/0040540 A1
(43) Pub. Date: Feb. 5, 2026

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Seungmin Lee, Suwon-si (KR); Minkyu Kang, Suwon-si (KR); Taemok Gwon, Suwon-si (KR); Gaeun Kim, Suwon-si (KR); Woongseop Lee, Suwon-si (KR); Joonsung Lim, Suwon-si (KR)

(21) Appl. No.: 19/283,603

(22) Filed: Jul. 29, 2025

(30) Foreign Application Priority Data
Aug. 5, 2024 (KR) 10-2024-0103709

(51) Int. Cl. H10B 41/27; H01L 23/00; H01L 25/18; H10B 41/10; H10B 41/35; H10B 43/10; H10B 43/27; H10B 43/35; H10B 80/00; H10D 80/20

(52) U.S. Cl. CPC H10B 41/27; H01L 25/18; H10B 41/10; H10B 41/35; H10B 43/10; H10B 43/27; H10B 43/35; H10B 80/00; H10D 80/20; H01L 24/32; H01L 24/48; H01L 2224/32145; H01L 2224/32225; H01L 2224/48147; H01L 2224/48227; H01L 2225/06506; H01L 2225/0651; H01L 2225/06524; H01L 2225/06562; H01L 2924/1438

(57) ABSTRACT

A device includes a plate layer; gate electrodes including first gate electrodes stacked on the plate layer and a second gate electrode on the first gate electrodes; a first channel structure extending through the first gate electrodes and including a first channel layer; a second channel structure extending through the second gate electrode and including a second channel layer; a channel connection portion on an uppermost surface of the first channel structure and electrically connecting the first channel layer to the second channel layer; and a horizontal insulating layer extending between an uppermost first gate electrode and the second gate electrode, wherein the horizontal insulating layer is on a level different from a level of the channel connection portion, and wherein the channel connection portion covers a portion of a lower surface of the second channel structure and exposes a portion of the lower surface of the second channel structure.

### CROSS-REFERENCE TO RELATED APPLICATION(S)

This application claims benefit of priority to Korean Patent Application No. 10-2024-0103709 filed on Aug. 5, 2024, in the Korean Intellectual Property Office, the disclosure of which is incorporated herein by reference in its entirety.

### BACKGROUND

Example embodiments of the present disclosure relate to a semiconductor device and a data storage system including the same.

A semiconductor device able to store high-capacity data in a data storage system requiring data storage has been desired for various applications. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested.

### SUMMARY

An example embodiment of the present disclosure may provide a semiconductor device having improved reliability.

An example embodiment of the present disclosure may provide a data storage system including a semiconductor device having improved reliability.

According to an example embodiment of the present disclosure, a semiconductor device includes a first semiconductor device structure including a substrate, circuit devices on the substrate, and circuit interconnection lines on the circuit devices; and a second semiconductor device structure on the first semiconductor device structure, wherein the second semiconductor device structure includes a plate layer; gate electrodes including first gate electrodes stacked and spaced apart from each other in a first direction perpendicular to an upper surface of the plate layer on the plate layer and a second gate electrode on the first gate electrodes; first channel structures extending through the first gate electrodes in the first direction, and each including a first channel layer; second channel structures extending through the second gate electrode, and each including a second channel layer electrically connected to the first channel layer; channel connection portions on uppermost surfaces of the first channel structures, and electrically connecting the first channel layers to the second channel layers, respectively; and a horizontal insulating layer extending between an uppermost first gate electrode among the first gate electrodes and the second gate electrode, wherein an upper surface of the horizontal insulating layer is on a level lower than a level of the uppermost surfaces of the first channel structures in the first direction where the upper surface of the plate layer provides a base reference plane, and wherein the horizontal insulating layer is spaced apart from the first channel layer in a second direction perpendicular to the first direction around each of the first channel structures.

According to an example embodiment of the present disclosure, a semiconductor device includes a plate layer; gate electrodes including first gate electrodes stacked and spaced apart from each other in a first direction perpendicular to an upper surface of the plate layer on the plate layer and a second gate electrode on the first gate electrodes; a first channel structure extending through the first gate electrodes in the first direction and including a first channel layer; a second channel structure extending through the second gate electrode, and including a second channel layer electrically connected to the first channel layer; a channel connection portion on an uppermost surface of the first channel structure and electrically connecting the first channel layer to the second channel layer; and a horizontal insulating layer extending between an uppermost first gate electrode among the first gate electrodes and the second gate electrode, wherein the horizontal insulating layer is on a level different from a level of the channel connection portion in the first direction, and wherein the channel connection portion covers a portion of a lower surface of the second channel structure and exposes a portion of the lower surface of the second channel structure.

According to an example embodiment of the present disclosure, a data storage system includes a semiconductor device storage device including a first semiconductor device structure including circuit devices, a second semiconductor device structure on the first semiconductor device structure, and an input/output pad electrically connected to the circuit devices; and a controller electrically connected to the semiconductor device storage device through the input/output pad and configured to control the semiconductor device storage device, wherein the second semiconductor device structure includes a plate layer; gate electrodes including first gate electrodes stacked and spaced apart from each other in a first direction perpendicular to an upper surface of the plate layer on the plate layer and a second gate electrode on the first gate electrodes; a first channel structure extending through the first gate electrodes in the first direction and including a first channel layer; a second channel structure extending through the second gate electrode, and including a second channel layer electrically connected to the first channel layer; a channel connection portion on an uppermost surface of the first channel structure and electrically connecting the first channel layer to the second channel layer; and a horizontal insulating layer extending horizontally between an uppermost first gate electrode among the first gate electrodes and the second gate electrode, and wherein an upper surface of the horizontal insulating layer is on a level lower than a level of the uppermost surface of the first channel structure in the first direction where the upper surface of the plate layer provides a base reference plane.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan view illustrating a semiconductor device according to an example embodiment of the present disclosure;

FIG. 2 is a cross-sectional view illustrating a semiconductor device according to an example embodiment of the present disclosure;

FIGS. 3A and 3B are enlarged views illustrating a portion of regions of a semiconductor device according to an example embodiment of the present disclosure;

FIGS. 4A and 4B are a cross-sectional view and an enlarged view illustrating a portion of a semiconductor device according to an example embodiment of the present disclosure;

FIG. 5 is an enlarged view illustrating a portion of a semiconductor device according to an example embodiment of the present disclosure;

FIG. 6 is an enlarged view illustrating a portion of a semiconductor device according to an example embodiment of the present disclosure;

FIGS. 7A and 7B are a cross-sectional view and an enlarged view illustrating a portion of a semiconductor device according to an example embodiment of the present disclosure;

FIG. 8 is an enlarged view illustrating a portion of a semiconductor device according to an example embodiment of the present disclosure;

FIG. 9 is a cross-sectional view illustrating a semiconductor device according to an example embodiment of the present disclosure;

FIGS. 10A to 10L are cross-sectional views illustrating a method of manufacturing a semiconductor device according to an example embodiment of the present disclosure;

FIG. 11 is a view illustrating a data storage system including a semiconductor device according to an example embodiment of the present disclosure;

FIG. 12 is a perspective view illustrating a data storage system including a semiconductor device according to an example embodiment of the present disclosure; and

FIG. 13 is a cross-sectional view illustrating a semiconductor package according to an example embodiment of the present disclosure.

### DETAILED DESCRIPTION

Hereinafter, embodiments of the present disclosure will be described as follows with reference to the accompanying drawings. Herein, like reference numerals will denote like elements, and redundant descriptions thereof will be omitted for conciseness. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will be understood that, although the terms “first,” “second,” etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. It is noted that aspects described with respect to one embodiment may be incorporated in different embodiments although not specifically described relative thereto. That is, all embodiments and/or features of any embodiments can be combined in any way and/or combination.

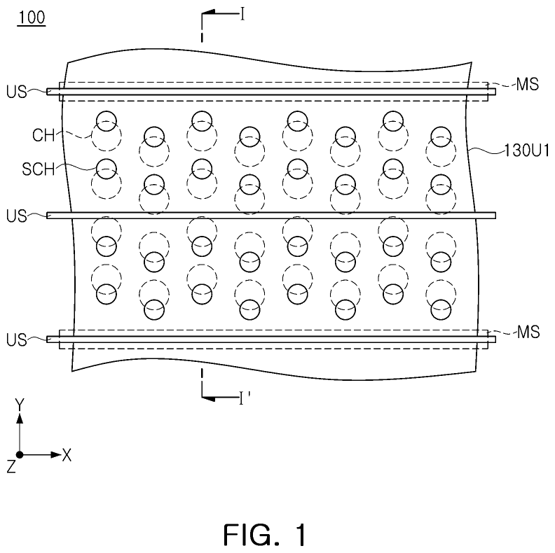

FIG. 1 is a plan view illustrating a semiconductor device according to an example embodiment.

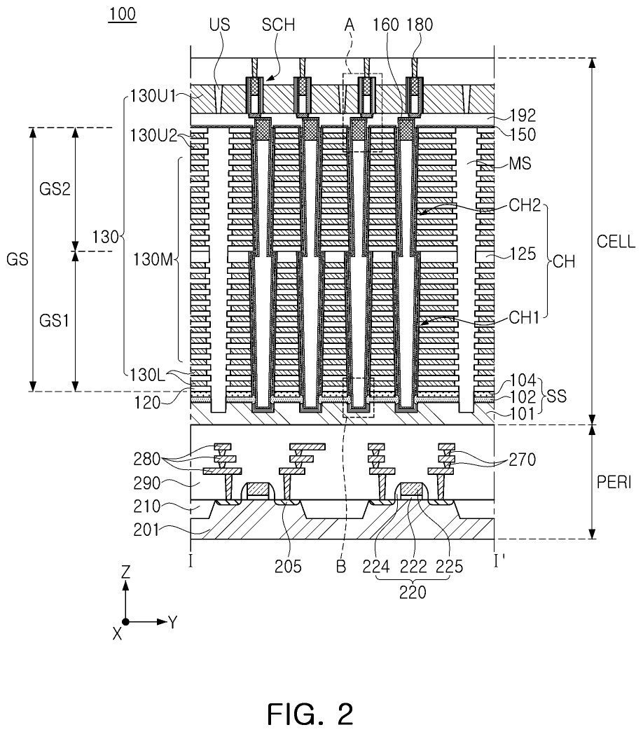

FIG. 2 is a cross-sectional view illustrating a semiconductor device according to an example embodiment. FIG. 2 illustrates a cross-section taken along line I-I′ in FIG. 1.

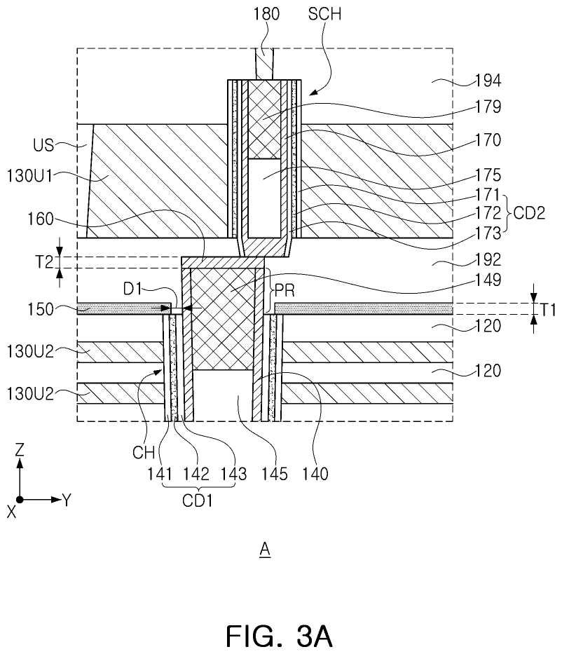

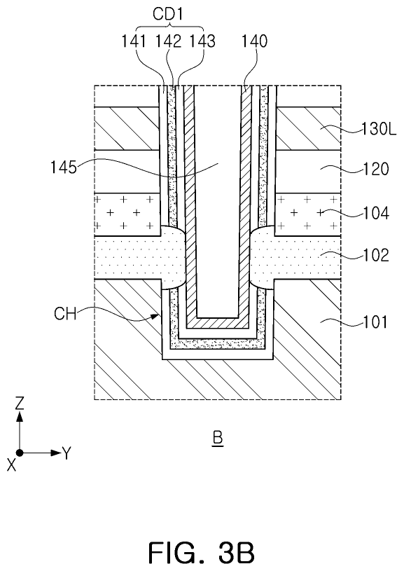

FIGS. 3A and 3B are enlarged views illustrating a portion of regions of a semiconductor device according to an example embodiment, illustrating regions “A” and “B” in FIG. 2, respectively.

Referring to FIGS. 1, 2, 3A, and 3B, a semiconductor device 100 may include a peripheral circuit region PERI, which is a first semiconductor device structure including a substrate 201, and a memory cell region CELL, which is a second semiconductor device structure including a plate layer 101. The memory cell region CELL may be disposed on the peripheral circuit region PERI. In example embodiments, conversely, the memory cell region CELL may be disposed below (in the Z-direction) the peripheral circuit region PERI. Only a portion of the components of the memory cell region CELL are illustrated in FIG. 1.

The peripheral circuit region PERI may include a substrate 201, impurity regions 205 and device isolation layers 210 in the substrate 201, circuit devices 220 disposed on the substrate 201, a peripheral region insulating layer 290, circuit contact plugs 270, and circuit interconnection lines 280.

The substrate 201 may have an upper surface extending in the X-direction and the Y-direction. The substrate 201 may have an active region defined by the device isolation layers 210. A portion of the active region may have impurity regions 205 disposed therein. The substrate 201 may include a semiconductor device material, such as a group IV semiconductor device, a group III-V compound semiconductor device, or a group II-VI compound semiconductor device. The substrate 201 may be provided as a bulk wafer or an epitaxial layer.

The circuit devices 220 may include a planar transistor. Each of the circuit devices 220 may include a circuit gate dielectric layer 222, a spacer layer 224, and a circuit gate electrode 225. The impurity regions 205 may be disposed as source/drain regions in the substrate 201 on both sides of the circuit gate electrode 225.

The peripheral region insulating layer 290 may be disposed on the circuit device 220 on the substrate 201. The peripheral region insulating layer 290 may include a plurality of insulating layers formed in different processes. The peripheral region insulating layer 290 may be formed of an insulating material.

The circuit contact plugs 270 and the circuit interconnection lines 280 may be included in a circuit interconnection structure electrically connected to the circuit devices 220 and the impurity regions 205. The circuit contact plugs 270 may have a cylindrical shape, and the circuit interconnection lines 280 may have a line shape. An electrical signal may be applied to the circuit device 220 by way of the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270 and may be disposed in a plurality of layers. The circuit contact plugs 270 and the circuit interconnection lines 280 may include a conductive material, for example, tungsten (W), copper (Cu), aluminum (Al), or the like, and each of components may further include a diffusion barrier. In example embodiments, the number of layers of the circuit contact plugs 270 and the circuit interconnection lines 280 may be varied.

The memory cell region CELL may include a source structure SS including a plate layer 101, gate electrodes 130 stacked on the source structure SS and having at least a portion forming a gate structure GS, interlayer insulating layers 120 alternately stacked with the gate electrodes 130 and forming the gate structure GS, first channel structures CH disposed to penetrate or extend through the gate structure GS, second channel structures SCH electrically connected to the first channel structures CH, channel connection portions 160 connecting the first channel structures CH to the second channel structures SCH, first separation regions MS penetrating or extending through the gate structure GS and extending in one direction, second separation regions US penetrating or extending through the first upper gate electrode 130U1 disposed in an uppermost portion of the gate electrodes 130, and a horizontal insulating layer 150 disposed between the gate structure GS and the first upper gate electrode 130U1. The memory cell region CELL may further include first and second horizontal conductive layers 102 and 104 on the plate layer 101, studs 180 on the second channel structures SCH, and first and second cell region insulating layers 192 and 194 covering at least a portion of the gate electrodes 130.

The plate layer 101 may have a plate shape and may function as at least a portion of a common source line of the semiconductor device 100. The plate layer 101 may have an upper surface extending in the X-direction and the Y-direction. The plate layer 101 may include a conductive material. For example, the plate layer 101 may include a semiconductor device material, such as a group IV semiconductor device, a group III-V compound semiconductor device, and/or a group II-VI compound semiconductor device. For example, the group IV semiconductor device may include silicon, germanium, and/or silicon-germanium. The plate layer 101 may further include impurities. The plate layer 101 may be provided as a polycrystalline semiconductor device layer, such as a polycrystalline silicon layer, and/or an epitaxial layer.

The first and second horizontal conductive layers 102 and 104 may be stacked in order on an upper surface of the plate layer 101. The first and second horizontal conductive layers 102 and 104 may be included in a source structure SS together with the plate layer 101. The source structure SS may function as a common source line of the semiconductor device 100. As illustrated in FIG. 3B, the first horizontal conductive layer 102 may be directly connected to the first channel layer 140 around the first channel layer 140.

The first and second horizontal conductive layers 102 and 104 may include a semiconductor device material, for example, polycrystalline silicon. At least one of the first or second horizontal conductive layers 102 and 104 may include impurities. In some example embodiments, an insulating layer having a relatively small thickness may be interposed between the first horizontal conductive layer 102 and the second horizontal conductive layer 104.

A portion of the gate electrodes 130 may be vertically stacked and spaced apart from on the plate layer 101 and may be included in a gate structure GS together with interlayer insulating layers 120. The gate structure GS may include first and second stack structures GS1 and GS2 vertically stacked. However, in example embodiments, the number of stack structures included in the gate structure GS may be varied. For example, in some example embodiments, the gate structure GS may include three or more stack structures or may be configured as a single stack structure. The number of gate electrodes 130 included in each of the first and second stack structures GS1 and GS2 may be the same or different. The first stack structure GS1 may further include an upper interlayer insulating layer 125 disposed in an uppermost portion and having a relatively large thickness.

The gate electrodes 130 may include a first upper gate electrode 130U1 included in string select transistors, second upper gate electrodes 130U2 included in erase transistors, memory gate electrodes 130M included in a plurality of memory cells, and lower gate electrodes 130L included in erase transistors and ground select transistors. The number of memory gate electrodes 130M forming the memory cells may be determined according to capacity of the semiconductor device 100. The first upper gate electrode 130U1 may be referred to as an upper select gate electrode, and at least one of the lower gate electrodes 130L may be referred to as a lower select gate electrode. In example embodiments, the number of each of the first upper gate electrode 130U1, the second upper gate electrodes 130U2, and the lower gate electrodes 130L may be 1 to 4 or more, and may have a structure the same as or different from a structure of the memory gate electrodes 130M. In some example embodiments, the second upper gate electrodes 130U2 and/or at least one lower gate electrode 130L may not be omitted. A portion of the gate electrodes 130, for example, the memory gate electrodes 130M adjacent to the second upper gate electrodes 130U2 or the lower gate electrodes 130L, may be dummy gate electrodes.

The gate electrodes 130, other than the first upper gate electrode 130U1, among the gate electrodes 130, may be referred to as first gate electrodes. The first gate electrodes may be included in the gate structure GS. The first upper gate electrode 130U1 may also be referred to as the second gate electrode and may be disposed in an uppermost portion to have a relatively large thickness.

As illustrated in FIG. 1, the first gate electrodes among the gate electrodes 130 may be separated from each other in the Y-direction by the first separation regions MS extending in the X-direction. The gate electrodes 130 between a pair of first separation regions MS may form a memory block, but an example embodiment of the memory block is not limited thereto.

The gate electrodes 130 may include a conductive material, such as a metal material or a semiconductor device material. For example, the first gate electrodes may include tungsten (W), and the second gate electrode, that is, the first upper gate electrode 130U1, may include polycrystalline silicon. In example embodiments, at least a portion of the gate electrodes 130 may further include a diffusion barrier, and for example, the diffusion barrier may include tungsten nitride (WN), tantalum nitride (TaN), titanium nitride (TiN), or a combination thereof.

The interlayer insulating layers 120 may be disposed between the first gate electrodes of the gate electrodes 130. The interlayer insulating layers 120 may also be disposed to be spaced apart from each other in a direction perpendicular to the upper surface of the plate layer 101 and to extend in the X-direction, similar to the gate electrodes 130. An upper interlayer insulating layer 125 having a relatively large thickness may be disposed in an uppermost portion of the first stack structure GS1. However, the relative thicknesses and arrangement positions of the interlayer insulating layers 120 and the upper interlayer insulating layer 125 may be varied in example embodiments. The interlayer insulating layers 120 and the upper interlayer insulating layer 125 may include an insulating material, such as silicon oxide and/lor silicon nitride.

The first channel structures CH may penetrate or extend through the gate electrodes 130, other than the first upper gate electrode 130U1, may extend in the Z-direction, and may be electrically connected to the plate layer 101. The first channel structures CH, together with the second channel structures SCH, may form a memory cell string each, and may be spaced apart from each other on the plate layer 101 while forming rows and columns. The first channel structures CH may be disposed to form a grid pattern on an X-Y plane or may be disposed in a zigzag or jagged pattern in one direction. The first channel structures CH may have a columnar shape and may have an inclined side surface having a width decreasing toward the plate layer 101.

The first channel structures CH may include first and second channel portions CH1 and CH2 stacked vertically (Z-direction), respectively. The first and second channel portions CH1 and CH2 may penetrate or extend through the first and second stack structures GS1 and GS2 of the gate structure GS, respectively. The first channel structure CH may have a form in which the first channel portion CH1 and the second channel portion CH2 in an upper portion are electrically connected to each other. The first and second channel portions CH1 and CH2 may have a form in which a width of an upper surface of the channel portion disposed in a lower portion is larger than a width of a lower surface of the channel portion disposed in an upper portion in a region in which the first and second channel portions CH1 and CH2 are electrically connected to each other or on an interfacial surface. The first channel structure CH may have bent portions due to a difference in widths at an interfacial surface between the first and second channel portions CH1 and CH2. However, in example embodiments, the number of channel portions stacked in the Z-direction in the first channel structure CH may be varied. The first channel portion CH1 may partially penetrate or extend into the source structure SS, and a lower end of the first channel portion CH1 may be positioned in the plate layer 101.

Each of the first channel structures CH may include a first channel layer 140, a first channel dielectric layer CD1, a first channel buried insulating layer 145, and a first channel pad 149 disposed in a lower channel hole. The first channel layer 140, the first channel dielectric layer CD1, and the first channel buried insulating layer 145 may be electrically connected to each other between the first and second channel portions CH1 and CH2.

The first channel layer 140 may be formed in an annular shape at least partially surrounding the first channel buried insulating layer 145 therein, but in example embodiments, the first channel layer 140 may have a columnar shape, such as a cylindrical shape or a prism shape without the first channel buried insulating layer 145. The first channel layer 140 may be electrically connected to the first horizontal conductive layer 102 in a lower portion. The first channel layer 140 may include a semiconductor device material, such as polycrystalline silicon or single crystal silicon. The first channel layer 140 may be an undoped layer or a layer doped at a lower concentration than the first channel pad 149.

The first channel dielectric layer CD1 may be disposed between the gate electrodes 130 and the first channel layer 140. The first channel dielectric layer CD1 may include a first blocking layer 141, a first charge storage layer 142, and a first tunneling layer 143 stacked in order from the gate electrodes 130. The first blocking layer 141 may include silicon oxide (SiO₂), silicon nitride (Si₃N₄), silicon oxynitride (SiON), a high-K dielectric material or a combination thereof. The first charge storage layer 142 may be a charge trap layer or a floating gate conductive layer. The first tunneling layer 143 may tunnel electric charges into the first charge storage layer 142 and may include, for example, silicon oxide (SiO₂), silicon nitride (Si₃N₄), silicon oxynitride (SiON), or a combination thereof. In some example embodiments, a portion of the first blocking layer 141 may extend horizontally (e.g., Y-direction) along the gate electrodes 130. The first channel pad 149 may be disposed only at an upper end of the second channel portion CH2. The first channel pad 149 may include, for example, doped polycrystalline silicon. A lower surface of the first channel pad 149 may be positioned on a level lower (Z-direction) than a level of an upper surface of an uppermost second upper gate electrode 130U2 among the second upper gate electrodes 130U2, but an example embodiment thereof is not limited thereto. In some example embodiments, the lower surface of the first channel pad 149 may be positioned on a level higher (Z-direction) than a level of an upper surface of the uppermost second upper gate electrode 130U2.

In each of the first channel structures CH, an upper surface of the first channel pad 149 and an upper surface of the first channel layer 140 may be coplanar with each other, and may form an uppermost surface of the first channel structure CH. An upper surface of the first channel dielectric layer CD1 may be positioned on a level lower (Z-direction) than a level of the uppermost surface of the first channel structure CH, and may be included in a portion of an upper surface of the first channel structure CH. The upper surface of the first channel dielectric layer CD1 may be positioned at substantially the same level (Z-direction) as a level of an upper surface of the gate structure GS and a lower surface of the horizontal insulating layer 150.

As illustrated in the enlarged view in FIG. 3A, an uppermost surface of the first channel structure CH may be positioned on a level higher (Z-direction) than a level of an upper surface of the horizontal insulating layer 150. Accordingly, the first channel structure CH may be disposed to protrude onto the gate structure GS and the horizontal insulating layer 150. The protrusion region PR of the first channel structure CH protruding onto the uppermost interlayer insulating layer 120 may be a region including the first channel pad 149 and the first channel layer 140. The first channel dielectric layer CD1 may be removed from the protrusion region PR, and accordingly, the side surface of the first channel layer 140 in the protrusion region PR may be at least partially exposed through the first channel dielectric layer CD1.

The second channel structures SCH may penetrate or extend through the first upper gate electrode 130U1, may extend in the Z-direction, and may be electrically connected to the first channel structures CH, respectively. The second channel structures SCH may be disposed on the first channel structures CH, respectively, and may be shifted from the first channel structures CH in the horizontal direction, for example, the Y-direction, but an example embodiment thereof is not limited thereto. The second channel structures SCH may also be shifted from the channel connection portions 160 in the horizontal direction, for example, the Y-direction. The second channel structures SCH may be disposed such that portions thereof may overlap the first channel structures CH in the Z-direction, respectively. As illustrated in the plan view in FIG. 1, a diameter of the second channel structures SCH may be smaller than a diameter of the first channel structures CH, but an example embodiment thereof is not limited thereto.

The second channel structures SCH may be spaced apart from the horizontal insulating layer 150 in the Z-direction, for example. Lower surfaces or lower ends of the second channel structures SCH may be positioned on a level higher (Z-direction) than a level of an upper surface of the horizontal insulating layer 150. The lower surfaces of the second channel structures SCH may be covered with the channel connection portions 160 and the first cell region insulating layer 192.

As illustrated in FIG. 3A, each of the second channel structures SCH may include a second channel layer 170, a second channel dielectric layer CD2, a second channel buried insulating layer 175, and a second channel pad 179, disposed in an upper channel hole. The second channel layer 170 may be formed in an annular shape at least partially surrounding the second channel buried insulating layer 175 disposed therein. The second channel layer 170 may be electrically connected to the first channel layer 140 of the first channel structure CH via the channel connection portion 160 connected to a lower surface of the second channel layer 170. The second channel dielectric layer CD2 may be disposed between the first upper gate electrode 130U1 and the second channel layer 170. The second channel dielectric layer CD2 may include a second blocking layer 171, a second charge storage layer 172, and a second tunneling layer 173 stacked in order from the first upper gate electrode 130U1. However, in some example embodiments, the second channel dielectric layer CD2 may be formed as a single insulating layer. The second channel buried insulating layer 175 may be disposed on an internal side of the second channel layer 170, and the second channel pad 179 may be disposed on an upper end of the second channel structure SCH on the second channel buried insulating layer 175.

For materials of the second channel layer 170, the second channel dielectric layer CD2, the second channel buried insulating layer 175, and the second channel pad 179, the description of materials of the first channel layer 140, the first channel dielectric layer CD1, the first channel buried insulating layer 145, and the first channel pad 149 may also be applied, respectively.

The channel connection portions 160 may be disposed on uppermost surfaces of the first channel structures CH, respectively. The channel connection portions 160 may be disposed between the first channel structures CH and the second channel structures SCH, and may electrically connect the first channel structures CH to the second channel structures SCH. Specifically, each of the channel connection portions 160 may be in contact with the first channel layer 140 and the first channel pad 149 of the first channel structure CH through a lower surface, may be in contact with the second channel layer 170 of the second channel structure SCH through an upper surface, and may electrically connect the first channel layer 140 to the second channel layer 170.

As illustrated in FIG. 3A, the channel connection portion 160 may cover an entire upper surface of the first channel layer 140 and an entire upper surface of the first channel pad 149, and may be disposed only on the first channel layer 140 and the first channel pad 149. The channel connection portion 160 may be disposed only on a region defined by an outer circumference of the first channel layer 140, and may not extend to an outer side of the outer circumference. The entirety of the channel connection portion 160 may overlap the first channel structure CH in the Z-direction, and particularly, in the example embodiment, the channel connection portion 160 may overlap the first channel layer 140 and the first channel pad 149 in the Z-direction. The channel connection portion 160 may expose a portion of a lower surface of the second channel layer 170 and may cover a portion of the lower surface. A center of the channel connection portion 160 in the Y-direction may be shifted from a center of the second channel structure SCH in the Y-direction.

The channel connection portion 160 may include the same material as a material of the second channel layer 170, for example, polycrystalline silicon, and may be integrated with the second channel layer 170. The channel connection portion 160 may include the same material as the first channel layer 140. The channel connection portion 160 may be formed in a process different from a process of forming the first channel layer 140, and the interfacial surface therebetween may or may not be distinct. The channel connection portion 160 may include the same material as a material of the first channel pad 149, and doping concentrations thereof may be different. For example, the first channel pad 149 may include N-type impurities, and the channel connection portion 160 may be an undoped layer or may include the N-type impurities at a relatively low concentration.

In the example embodiment, as the first channel layer 140 and the first channel pad 149 are entirely covered by the channel connection portion 160 and are spaced apart from the horizontal insulating layer 150, it is possible to prevent or mitigate the issue of threshold voltage dispersion of the string select transistor caused by trapped electrons on a layer on the first channel layer 140 and the first channel pad 149 during operation of the semiconductor device 100.

The horizontal insulating layer 150 may be disposed between the first upper gate electrode 130U1 and the second upper gate electrode 130U2 and may extend horizontally, e.g., Y-direction. The horizontal insulating layer 150 may be used as an etch stop layer when the second channel structures SCH is formed, and may also be used when the channel connection portion 160 is formed.

An upper surface of the horizontal insulating layer 150 may be positioned on a level lower (Z-direction) than a level of uppermost surfaces of the first channel structures CH. For example, the upper surface of the horizontal insulating layer 150 may be positioned on a level between an upper surface and a lower surface of the first channel pad 149 in the Z-direction. The horizontal insulating layer 150 may overlap the first channel pad 149 in the horizontal direction, for example, in the X-direction and the Y-direction. The horizontal insulating layer 150 may be disposed to at least partially surround the first channel layers 140 on a plane and may be spaced apart from side surfaces of the first channel layers 140 in the horizontal direction, e.g., X-direction or Y-direction. The horizontal insulating layer 150 may cover a portion of an upper surface of the first channel dielectric layer CD1 and may be in contact with the portion of the upper surface. The horizontal insulating layer 150 may expose the other portion of the upper surface of the first channel dielectric layer CD1. For example, the horizontal insulating layer 150 may cover an upper surface of the first blocking layer 141 and a portion of an upper surface of the first charge storage layer 142 of the first channel dielectric layer CD1, and may expose an upper surface of the first tunneling layer 143, but an example embodiment of the horizontal insulating layer 150 is not limited thereto. In some example embodiments, the horizontal insulating layer 150 may expose the entire upper surface of the first channel dielectric layer CD1.

The horizontal insulating layer 150 may be spaced apart from the channel connection portion 160. The horizontal insulating layer 150 may be disposed on a level (Z-direction) different from a level of the channel connection portion 160, and an upper surface of the horizontal insulating layer 150 may be disposed on a level lower (Z-direction) than a level of an upper surface of the channel connection portion 160. Because the horizontal insulating layer 150 is used in forming the channel connection portion 160, a first thickness T1 of the horizontal insulating layer 150 may be substantially the same as a second thickness T2 of the channel connection portion 160. The first thickness T1 may also be substantially the same as a spacing distance D1 between the first channel layer 140 and the horizontal insulating layer 150.

The horizontal insulating layer 150 may include an insulating material, and may include a material different from a material of the uppermost interlayer insulating layer 120 and the first cell region insulating layer 192. The horizontal insulating layer 150 may include a nitride, and may include, for example, one or more of SiN, SiON, SiCN, and/or SiOCN.

The first separation regions MS may penetrate or extend through at least a portion of the gate electrodes 130 and may extend in the X-direction. The first separation regions MS may be disposed to penetrate or extend through the gate electrodes 130 other than the first upper gate electrode 130U1. As illustrated in FIG. 1, the first separation regions MS may be disposed parallel to each other.

As illustrated in FIG. 2, the first separation regions MS may penetrate or extend through a portion of the gate electrodes 130 stacked on the plate layer 101, may further penetrate or extend through the first and second horizontal conductive layers 102 and 104 therebelow, and may be connected to the plate layer 101. The first separation regions MS may have a shape of which a width may decrease toward the plate layer 101 due to a relatively high aspect ratio. Side surfaces of the first separation regions MS may include regions protruding toward the gate electrodes 130. The first separation regions MS may include an insulating material, for example, silicon oxide, silicon nitride, and/or silicon oxynitride.

The second separation regions US may extend in the X-direction on the first separation regions MS and between the first separation regions MS adjacent to each other, as illustrated in FIG. 1. The second separation regions US may penetrate or extend through the first upper gate electrode 130U1 disposed in an uppermost portion of the gate electrodes 130. The second separation regions US may divide the first upper gate electrode 130U1 into a plurality of regions, as illustrated in FIG. 2. The second separation regions US may include an insulating material, for example, silicon oxide, silicon nitride, or silicon oxynitride.

The studs 180 may be included in a cell interconnection structure electrically connected to memory cells in the memory cell region CELL. The studs 180 may be electrically connected to the second channel structures SCH and may be electrically connected to the first channel structures CH. The studs 180 may have a plug form, but an example embodiment thereof is not limited thereto, and the studs 180 may also have a line form. The studs 180 may include a metal, for example, tungsten (W), copper (Cu), aluminum (Al), or the like.

The first and second cell region insulating layers 192 and 194 may at least partially cover the gate structure GS, the horizontal insulating layer 150, and the first upper gate electrode 130U1. Each of the first and second cell region insulating layers 192 and 194 may include a plurality of insulating layers in example embodiments. The first and second cell region insulating layers 192 and 194 may be formed of an insulating material, for example, one or more of silicon oxide, silicon nitride, and/or silicon oxynitride.

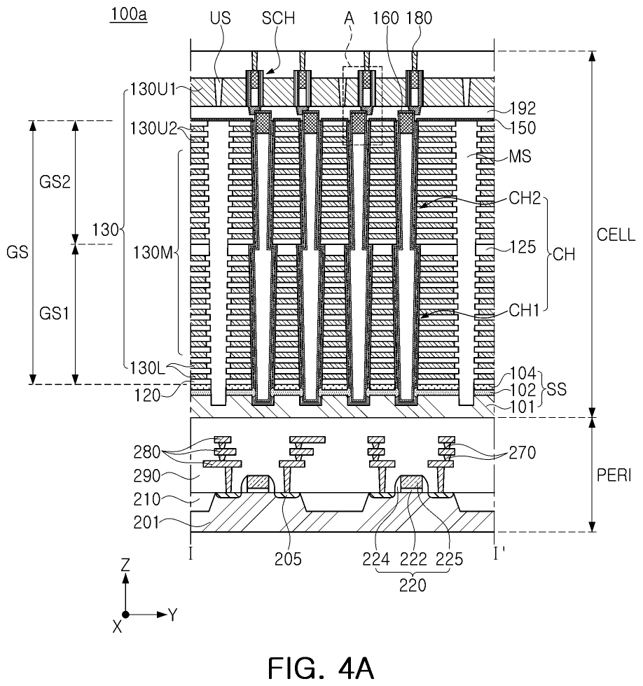

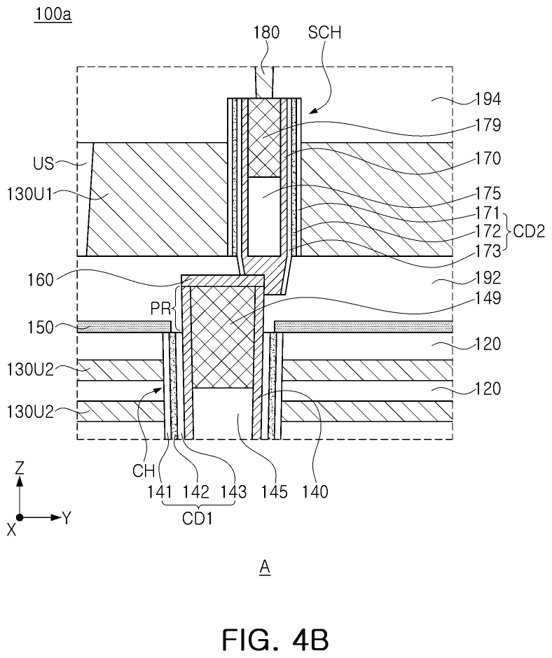

FIGS. 4A and 4B are a cross-sectional view and an enlarged view illustrating a portion of a semiconductor device according to an example embodiment, illustrating regions corresponding to FIGS. 2 and 3A, respectively.

Referring to FIG. 4A and FIG. 4B, in a semiconductor device 100a, a second channel structure SCH may cover a portion of a side surface of a protrusion region PR of a first channel structure CH. The second channel structure SCH may extend downwardly (Z-direction) along the side surface of the protrusion region PR in one side of the first channel structure CH. The second channel structure SCH may be in contact with a portion of the side surface of the first channel structure CH. The second channel layer 170 of the second channel structure SCH may cover a portion of a side surface of the channel connection portion 160 and a portion of a side surface of the first channel layer 140.

Also in the example embodiment, the second channel structure SCH may be spaced apart from the horizontal insulating layer 150, and a lower end of the second channel structure SCH may be positioned on a level higher (Z-direction) than a level of an upper surface of the horizontal insulating layer 150. In example embodiments, the shape of the lower surface of the second channel buried insulating layer 175 of the second channel structure SCH and the surface of the second channel layer 170 in contact therewith may be varied, and for example, the lower surface may have a shape tilted to one side to correspond to the shape of the second channel structure SCH.

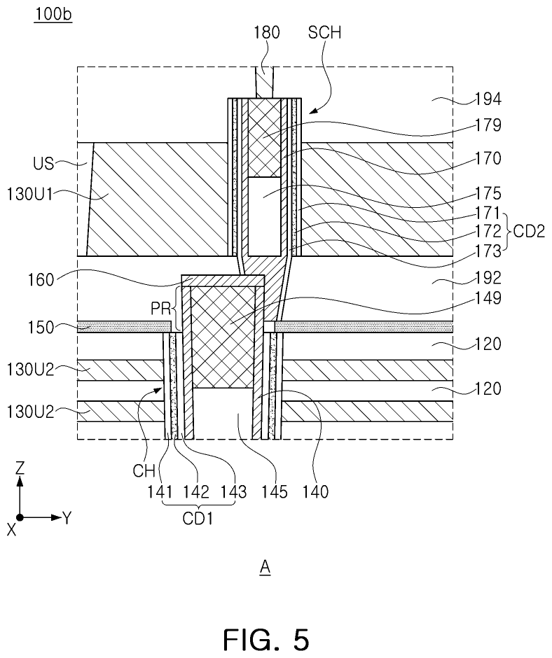

FIG. 5 is an enlarged view illustrating a portion of a semiconductor device and corresponding to a region shown in FIG. 4B according to an example embodiment.

Referring to FIG. 5, in a semiconductor device 100b, a second channel structure SCH may cover a portion of a side surface of a protrusion region PR of a first channel structure CH. However, differently from the example embodiment of FIGS. 4A and 4B, the second channel structure SCH may also be in contact with an upper surface of the horizontal insulating layer 150, and a lower end of the second channel structure SCH may be positioned at substantially the same level (Z-direction) as a level of the upper surface of the horizontal insulating layer 150. In example embodiments, the shape of the lower surface of the second channel buried insulating layer 175 of the second channel structure SCH and the surface of the second channel layer 170 in contact therewith may be varied.

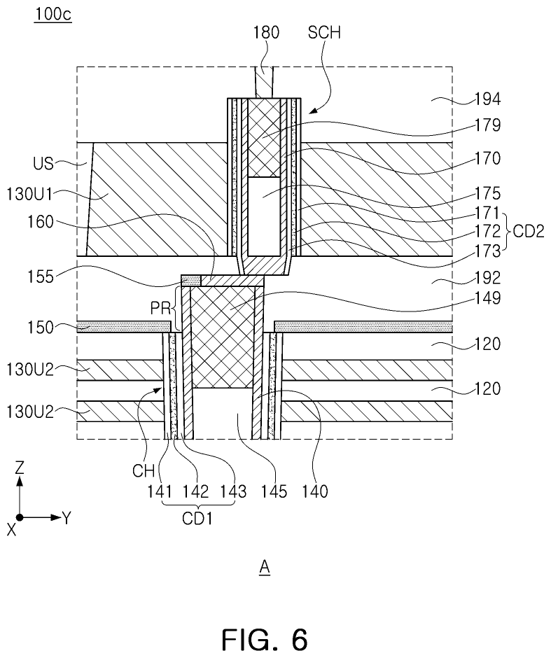

FIG. 6 is an enlarged view illustrating a portion of a semiconductor device and corresponding to a region shown in FIG. 3A according to an example embodiment.

Referring to FIG. 6, a memory cell region CELL of a semiconductor device 100c may further include an upper-surface insulating layer 155 disposed on an uppermost surface of at least one first channel structure CH. In the example embodiment, the channel connection portion 160 may be disposed on a portion of the uppermost surface of the first channel structure CH, and the upper-surface insulating layer 155 may be disposed on the other portion of the uppermost surface. The upper-surface insulating layer 155 may have substantially the same thickness as a thickness of the channel connection portion 160, and an upper surface of the upper-surface insulating layer 155 may be coplanar with an upper surface of the channel connection portion 160. The upper-surface insulating layer 155 may be disposed on an outer side of the second channel structure SCH, and may be disposed on a region relatively far from a region of the uppermost surface on which the second channel structure SCH is disposed. The upper surface of the insulating layer 155 may include the same material as a material of the horizontal insulating layer 150, for example, nitride.

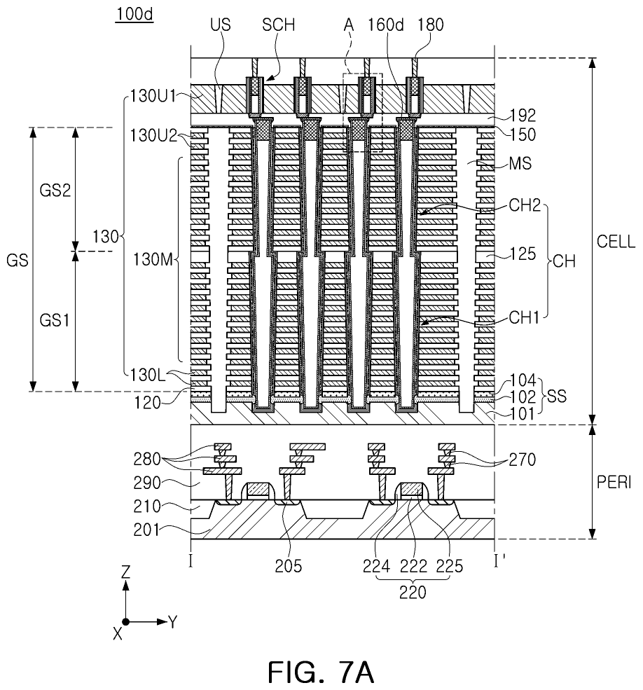

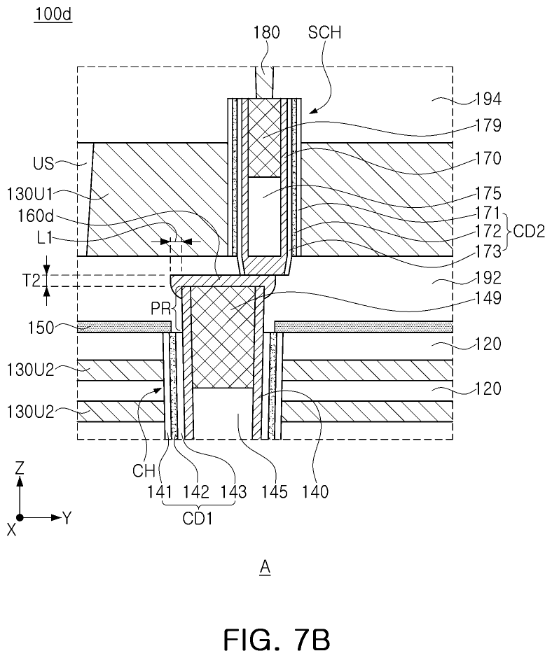

FIGS. 7A and 7B are a cross-sectional view and an enlarged view illustrating a portion of a semiconductor device and corresponding to regions shown in FIGS. 2 and 3A, respectively, according to an example embodiment.

Referring to FIGS. 7A and 7B, in a semiconductor device 100d, a channel connection layer 160d may be configured to be expand from an uppermost surface of the first channel structure CH and may cover a portion of a side surface of the first channel structure CH. The channel connection layer 160d may be in contact with a side surface of the first channel structure CH, and may be, for example, in contact with a side surface of the first channel layer 140.

A length L1 of the channel connection layer 160d expanding from the uppermost surface of the first channel structure CH may be equal to or less than a second thickness T2 of the channel connection layer 160d on the uppermost surface. The channel connection layer 160d may also have a thickness equal to or less than the second thickness T2 on the side surface of the first channel structure CH. In example embodiments, the length and shape of the side surface of the first channel structure CH in contact with the channel connection layer 160d may be varied.

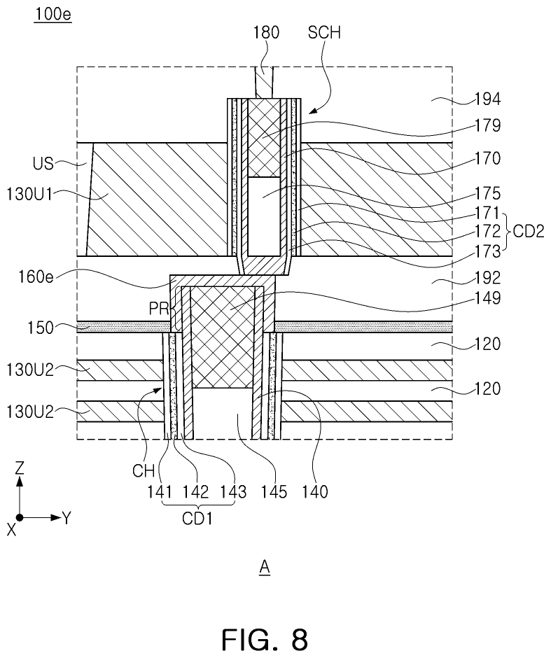

FIG. 8 is an enlarged view illustrating a portion of a semiconductor device and corresponding to a region shown in FIG. 7B according to an example embodiment.

Referring to FIG. 8, in a semiconductor device 100e, the channel connection layer 160e may extend from an uppermost surface of the first channel structure CH along a portion of a side surface of the first channel structure CH and may be in contact with a side surface of the first channel layer 140 and the horizontal insulating layer 150. The channel connection layer 160e may extend from an uppermost surface of the first channel structure CH along a side surface with a relatively constant thickness. The channel connection layer 160e may cover the entire side surface of the protrusion region PR of the first channel structure CH. The channel connection layer 160e may also be in contact with an upper surface of the first channel dielectric layer CD1 at a lower end.

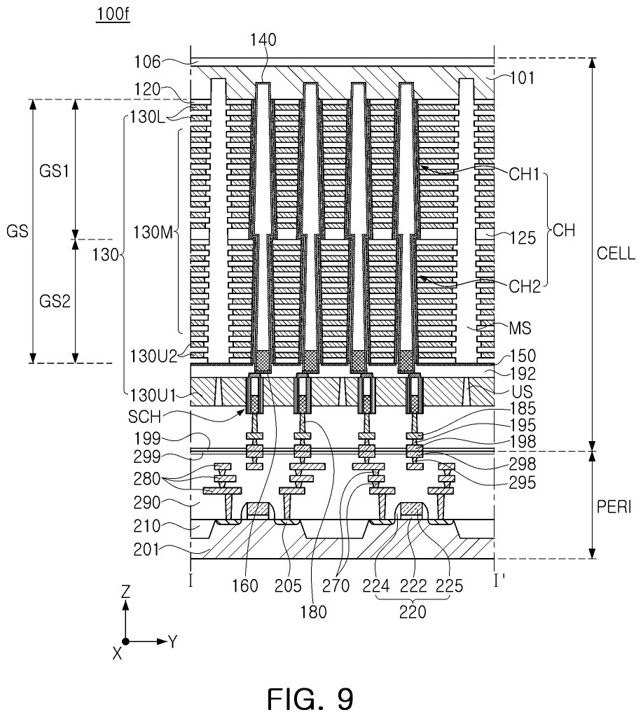

FIG. 9 is a cross-sectional view illustrating a semiconductor device and corresponding to a region shown in FIG. 2 according to an example embodiment.

Referring to FIG. 9, a semiconductor device 100f may include a first semiconductor device structure S1 and a second semiconductor device structure S2 bonded to each other by a wafer bonding method.

The description of the peripheral circuit region PERI described above with reference to FIG. 2 may be applied to the first semiconductor device structure S1. However, the first semiconductor device structure S1 may further include first bonding vias 295, first bonding metal layers 298, and first bonding insulating layer 299, which may be a bonding structure. The first bonding vias 295 may be disposed in an upper portion of circuit interconnection lines 280 disposed in an uppermost portion, and may be connected to the circuit interconnection lines 280. At least a portion of the first bonding metal layers 298 may be electrically connected to the first bonding vias 295 on the first bonding vias 295. The first bonding metal layers 298 may be electrically connected to the second bonding metal layers 198 of the second semiconductor device structure S2. The bonding metal layers 298 may provide an electrical connection path according to bonding between the first semiconductor device structure S1 and the second semiconductor device structure S2 together with the second bonding metal layers 198. A portion of the first bonding metal layers 298 may not be electrically connected to the circuit interconnection lines 280 in a lower portion and may be disposed only for bonding. The first bonding vias 295 and the first bonding metal layers 298 may include a conductive material, for example, copper (Cu). The first bonding insulating layer 299 may be disposed around the first bonding metal layers 298. The first bonding insulating layer 299 may also function as a diffusion barrier of the first bonding metal layers 298 and may include, for example, one or more of SiN, SiON, SiCN, SiOC, SiOCN, and/or SiO.

Unless otherwise indicated, the description of the memory cell region CELL described above with reference to FIGS. 1, 2, 3A, and 3B may be applied to the second semiconductor device structure S2. The second semiconductor device structure S2 may further include cell interconnection lines 185, which may be an interconnection structure, and may further include second bonding vias 195, second bonding metal layers 198, and second bonding insulating layer 199, which may be a bonding structure. The second semiconductor device structure S2 may further include a passivation layer 106 covering an upper surface of the plate layer 101.

The cell interconnection lines 185 may be electrically connected to studs 180. However, in example embodiments, the number of layers and the arrangement patterns of contact plugs and interconnection lines included in the interconnection structure may be varied. The cell interconnection lines 185 may be formed of a conductive material, and may include one or more of, for example, tungsten (W), aluminum (Al), and/or copper (Cu).

The second bonding vias 195 and the second bonding metal layers 198 may be disposed below (Z-direction) the cell interconnection lines 185 in a lowermost portion. The second bonding vias 195 may electrically connect the cell interconnection lines 185 to the second bonding metal layers 198, and the second bonding metal layers 198 may be bonded to the first bonding metal layers 298 of the first semiconductor device structure S1. The second bonding insulating layer 199 may be bonded and electrically connected to the first bonding insulating layer 299 of the first semiconductor device structure S1. The second bonding vias 195 and the second bonding metal layers 198 may include a conductive material, for example, copper (Cu). The second bonding insulating layer 199 may include, for example, one or more of SiO, SiN, SiCN, SiOC, SiON, and/or SiOCN.

The first and second semiconductor device structures S1 and S2 may be bonded to each other by bonding between the first bonding metal layers 298 and the second bonding metal layers 198 and bonding between the first bonding insulating layer 299 and the second bonding insulating layer 199. The bonding between the first bonding metal layers 298 and the second bonding metal layers 198 may be, for example, copper (Cu)-to-copper (Cu) bonding, and the bonding between the first bonding insulating layer 299 and the second bonding insulating layer 199 may be, for example, dielectric-to-dielectric bonding, such as SiCN-to-SiCN bonding. The first and second semiconductor device structures S1 and S2 may be bonded to each other by hybrid bonding including copper (Cu)-to-copper (Cu) bonding and dielectric-to-dielectric bonding.

In the example embodiment, the second semiconductor device structure S2 may not include the first and second horizontal conductive layers 102 and 104 (see FIG. 2). The first channel structures CH may be directly connected to the plate layer 101 while the first channel layers 140 is exposed through an upper end. However, the electrical connection between the first channel structures CH and the common source line may be varied in example embodiments, and, the first channel structures CH and the source structure SS may have the same structure as in the example embodiment in FIG. 2.

The passivation layer 106 may be disposed on an upper surface of the plate layer 101 and may be configured to protect the semiconductor device 100f. The passivation layer 106 may include one or more of an insulating material, for example, silicon oxide, silicon nitride, and/or silicon carbide.

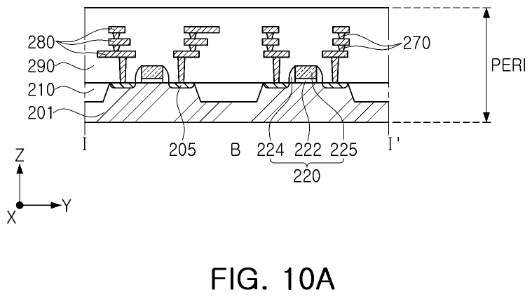

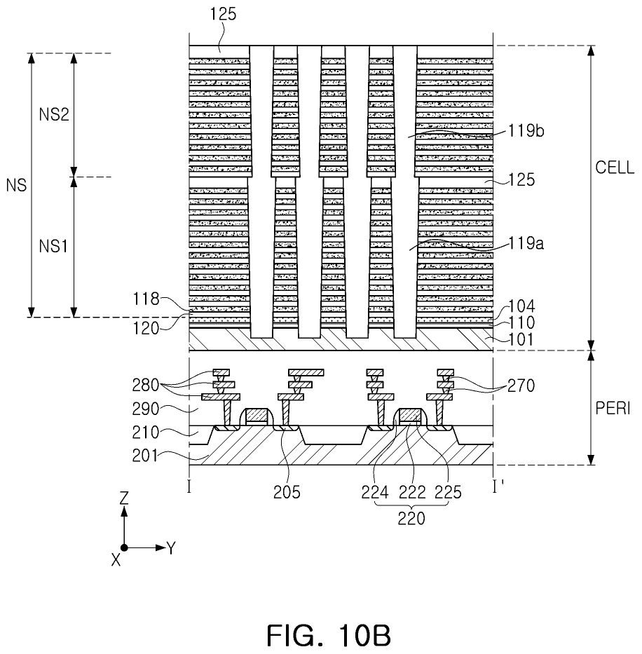

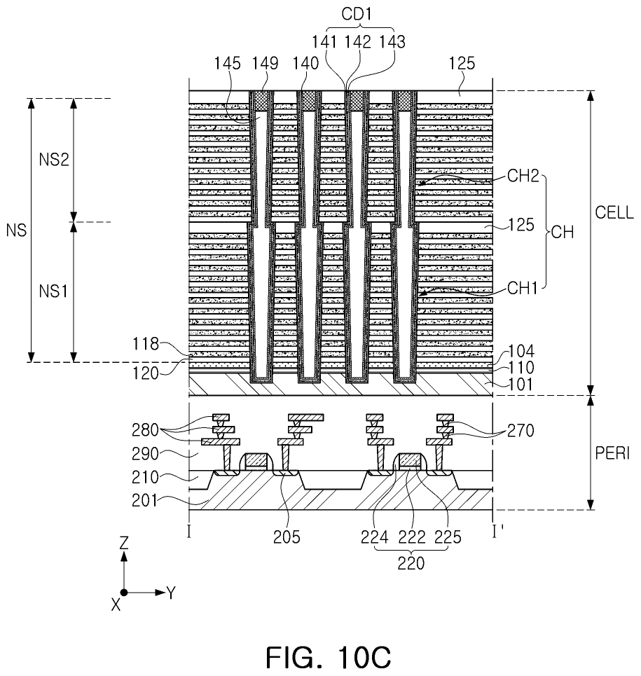

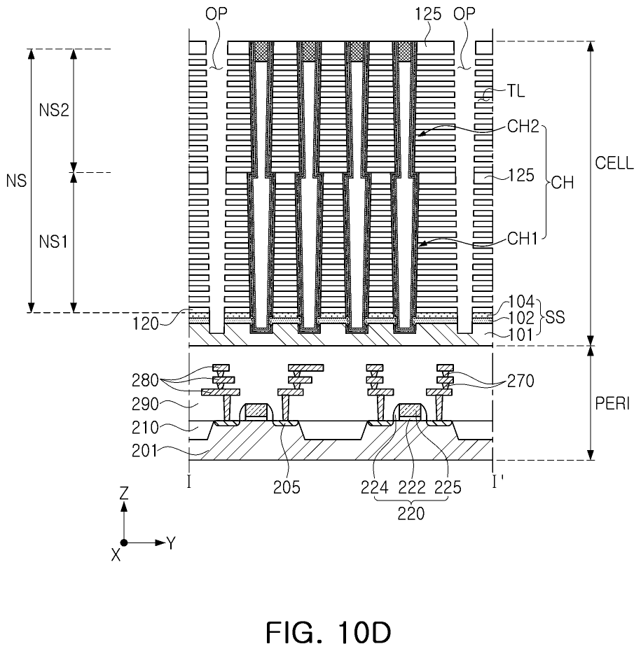

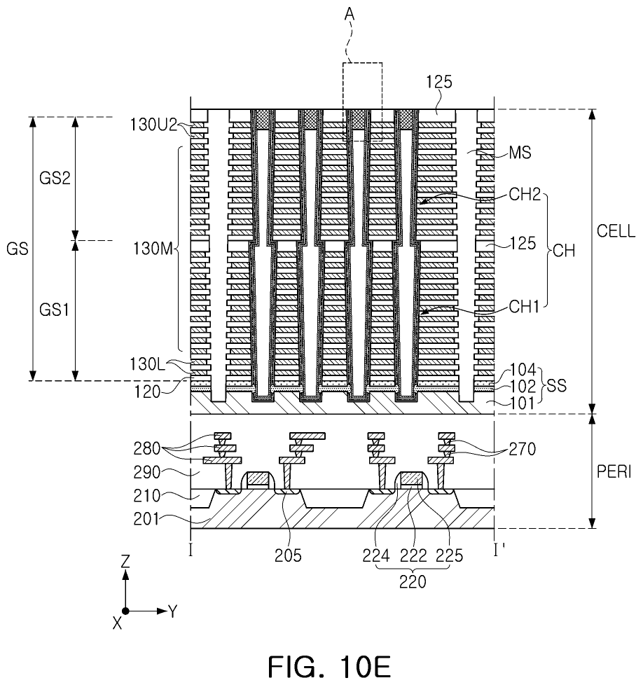

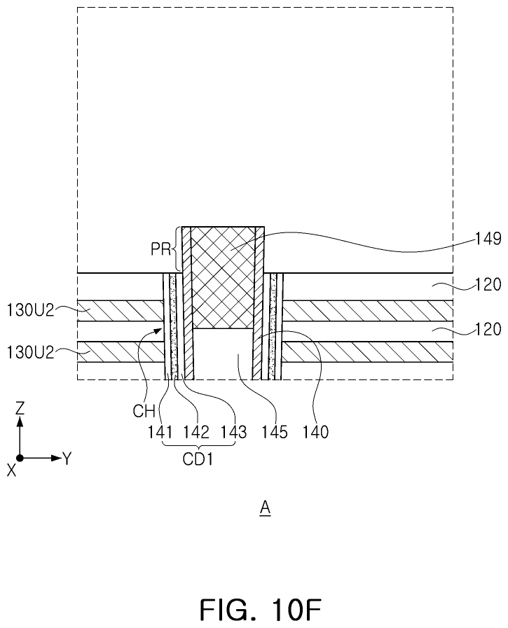

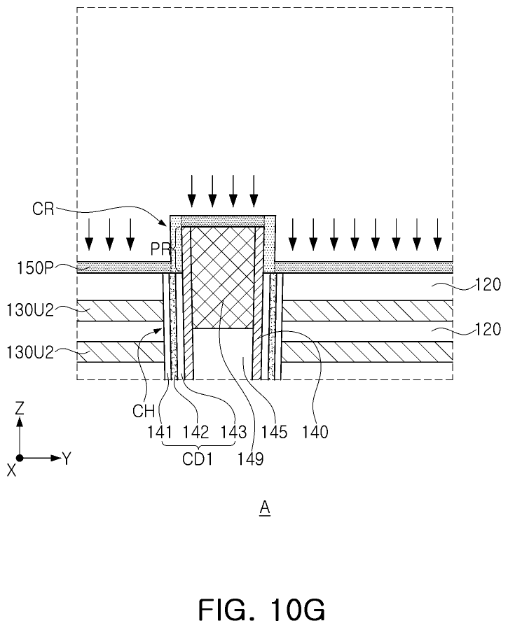

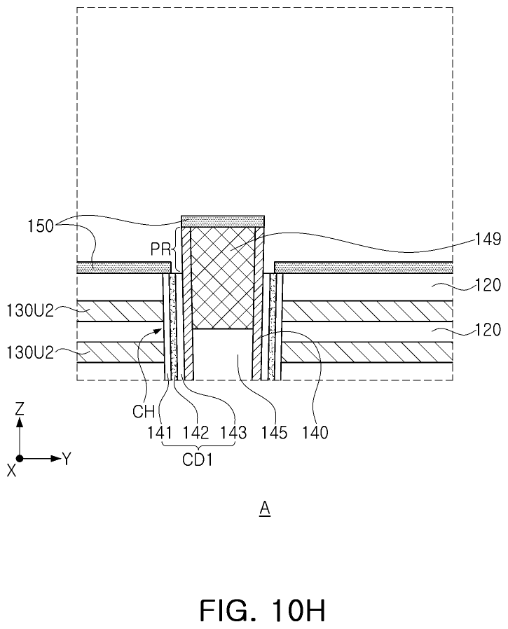

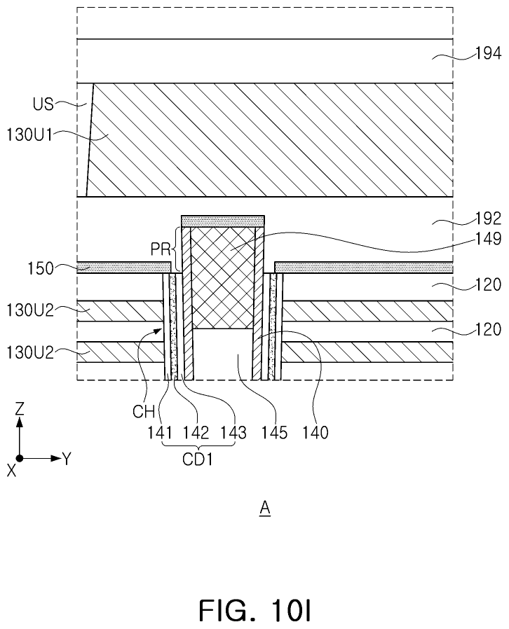

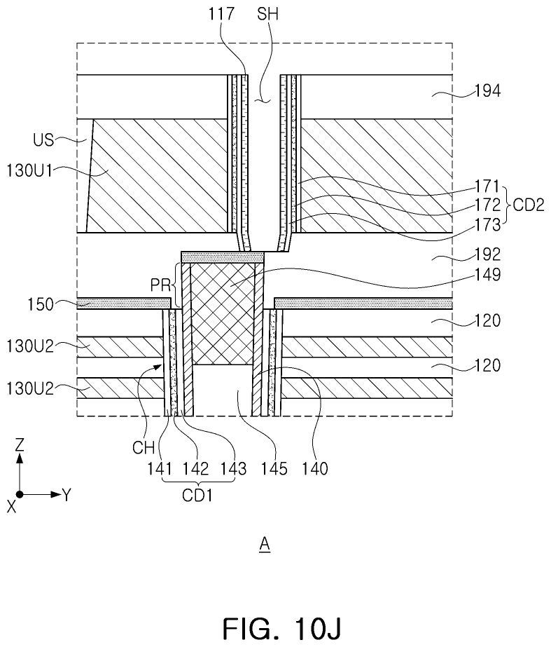

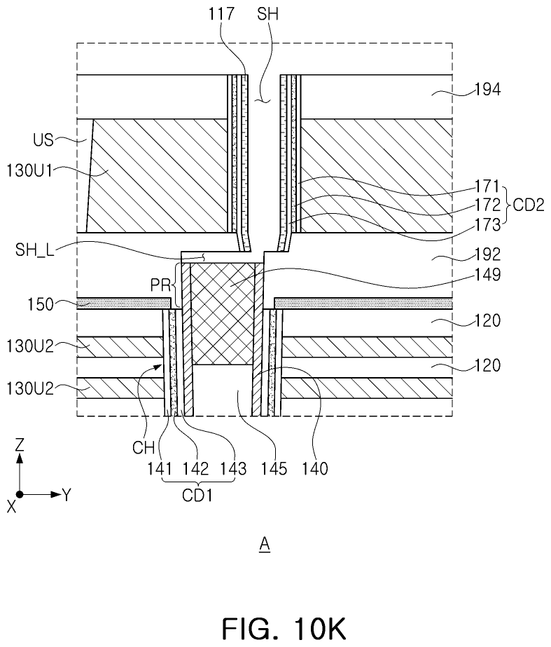

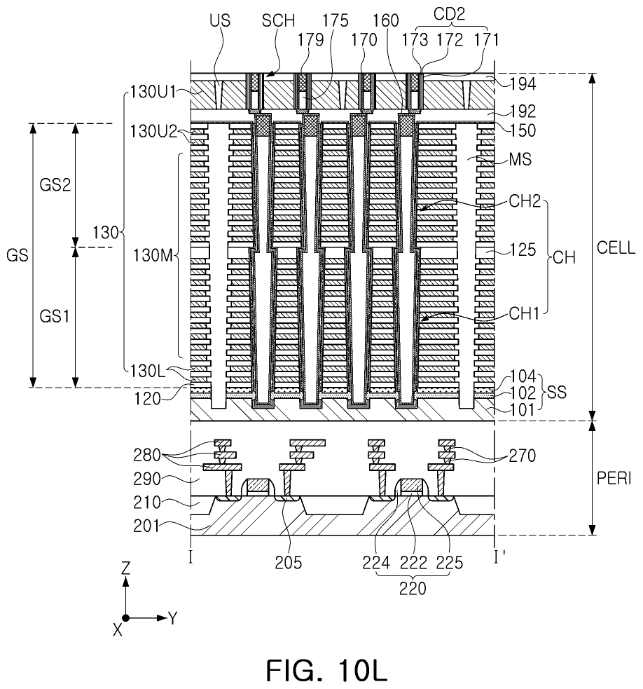

FIGS. 10A to 10L are cross-sectional views illustrating a method of manufacturing a semiconductor device according to an example embodiment. FIGS. 10A, 10B, 10C, 10D, 10E, and 10L illustrate cross-sections corresponding to FIG. 2, and FIGS. 10F, 10G, 10H, 10I, 10J, and 10K illustrate regions corresponding to region “A” in FIG. 10E.

Referring to FIG. 10A, circuit devices 220, a circuit interconnection structure, and a peripheral region insulating layer 290 included in a peripheral circuit region PERI may be formed on a substrate 201.

First, device isolation layers 210 may be formed in the substrate 201, and circuit gate dielectric layer 222 and circuit gate electrode 225 may be formed in order on the substrate 201. The device isolation layers 210 may be formed, for example, by a shallow trench isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of one or more of polycrystalline silicon and/or a metal silicide layer, but an example embodiment thereof is not limited thereto. Thereafter, a spacer layer 224 and impurity regions 205 may be formed on both sidewalls of the circuit gate dielectric layer 222 and the circuit gate electrode 225. In example embodiments, the spacer layer 224 may be formed as a plurality of layers. The impurity regions 205 may be formed by performing an ion implantation process.

The circuit contact plugs 270 of the circuit interconnection structures may be formed by forming a portion of the peripheral region insulating layer 290, etching and removing a portion of the peripheral region insulating layer 290, and at least partially filling a conductive material therein. The circuit interconnection lines 280 may be formed, for example, by depositing a conductive material and patterning the material.

The peripheral region insulating layer 290 may include a plurality of insulating layers. The peripheral region insulating layer 290 may be a portion in each of processes of forming the circuit interconnection structure. Accordingly, a peripheral circuit region PERI may be formed.

Referring to FIG. 10B, a plate layer 101, in which a memory cell region CELL is provided, a source insulating layer 110, and a second horizontal conductive layer 104 may be formed on a peripheral circuit region PERI, and mold structure NS and first and second vertical sacrificial layers 119a and 119b may be formed.

The plate layer 101 may be formed on the peripheral region insulating layer 290. The plate layer 101 may be formed of, for example, polycrystalline silicon and may be formed by a CVD process. The polycrystalline silicon forming the plate layer 101 may include impurities.

The source insulating layer 110 may include first to third source insulating layers stacked in order on the plate layer 101. The source insulating layer 110 may be layers of which a portion is replaced with the first horizontal conductive layer 102 in FIG. 2 through a subsequent process. The first and third source insulating layers may include a material different from a material of the second source insulating layer. For example, the first and third source insulating layers may be formed of the same material as the interlayer insulating layers 120, and the second source insulating layer may be formed of the same material as the sacrificial insulating layers 118 formed subsequently. The second horizontal conductive layer 104 may be formed on the source insulating layer 110.

The first mold structure NS1 may be formed by alternately stacking sacrificial insulating layers 118 and interlayer insulating layers 120 on the second horizontal conductive layer 104 on a level (Z-direction) at which the first stack structure GS1 (see FIG. 2) is disposed. An upper interlayer insulating layer 125 may be formed at an uppermost end.

The sacrificial insulating layers 118 may be layers of which at least a portion is replaced with gate electrodes 130 (see FIG. 2) through a subsequent process. The sacrificial insulating layers 118 may be formed of a material different from a material of the interlayer insulating layers 120 and the upper interlayer insulating layer 125, and may be formed of a material etched with etch selectivity under specific etching conditions with respect to the interlayer insulating layers 120 and the upper interlayer insulating layer 125. For example, the interlayer insulating layer 120 and the upper interlayer insulating layer 125 may be formed of one or more of silicon oxide and/or silicon nitride, and the sacrificial insulating layers 118 may be formed of a material different from a material of the interlayer insulating layer 120 selected from among silicon, silicon oxide, silicon carbide, and/or silicon nitride. In example embodiments, the number of the interlayer insulating layers 120 and the sacrificial insulating layers 118 and thicknesses thereof may be varied from the illustrated examples. The first vertical sacrificial layers 119a may be formed to penetrate or extend through the first mold structure NS1. The first vertical sacrificial layers 119a may include, for example, carbon.

The second mold structure NS2 and the second vertical sacrificial layers 119b may be formed on the first mold structure NS1 in the same manner as the first mold structure NS1 and the first vertical sacrificial layers 119a, respectively. The second vertical sacrificial layers 119b may be connected to the first vertical sacrificial layers 119a, respectively.

Referring to FIG. 10C, the first channel structures CH penetrating or extending through the mold structure NS may be formed.

The first channel structures CH may be formed by forming lower channel holes by removing the first and second vertical sacrificial layers 119a and 119b and depositing at least a portion of the first channel dielectric layer CD1, the first channel layer 140, the first channel buried insulating layer 145, and the first channel pad 149 in order in the lower channel holes.

The first channel dielectric layer CD1 may be formed to have a uniform thickness using an ALD or CVD process. In this process, the entirety or a portion of the first channel dielectric layer CD1 may be formed, and at least a portion extending vertically to the plate layer 101 along the first channel structures CH may be formed in this process. The first channel layer 140 may be formed on the first channel dielectric layer CD1 in the lower channel holes. The first channel buried insulating layer 145 may be formed to at least partially fill the lower channel holes and may be an insulating material. The first channel pad 149 may be formed by partially removing the first channel buried insulating layer 145 from an upper end of the lower channel hole and depositing a conductive material, and may be formed of, for example, polycrystalline silicon.

Referring to FIG. 10D, the sacrificial insulating layers 118 may be removed.

Openings OP penetrating the sacrificial insulating layers 118 and the interlayer insulating layers 120 and extending to the plate layer 101 may be formed in positions of the first separation regions MS (see FIG. 2). Thereafter, by forming sacrificial spacer layers in the openings OP and performing an etch-back process, the source insulating layer 110 may be selectively removed, and a portion of the exposed first channel dielectric layer CD1 may also be removed together. The first horizontal conductive layer 102 may be formed by depositing a conductive material in the region from which the source insulating layer 110 is removed, and the sacrificial spacer layers may be removed from the openings OP. By this process, the first horizontal conductive layer 102 may be formed, and the source structure SS including the first horizontal conductive layer 102 may be formed.

The sacrificial insulating layers 118 may be selectively removed, for example, using wet etching, with respect to the interlayer insulating layers 120, the upper interlayer insulating layers 125, the second horizontal conductive layer 104, and the first channel structures CH. Accordingly, gate tunnel portions TL may be formed in the region from which the sacrificial insulating layers 118 are removed.

Referring to FIG. 10E, gate electrodes 130 and first separation regions MS may be formed.

The gate electrodes 130 may be formed by depositing a conductive material in the gate tunnel portions TL. The conductive material may include a metal, polycrystalline silicon, and/or a metal silicide material. In some example embodiments, a portion of the first channel dielectric layer CD1 may be formed prior to forming the gate electrodes 130. Accordingly, a gate structure GS including first and second stack structures GS1 and GS2 may be formed.

After the gate electrodes 130 is formed, first separation regions MS may be formed by depositing an insulating material in the openings OP.

Referring to FIG. 10F, a portion of the upper interlayer insulating layer 125 and a portion of the first channel dielectric layer CD1 may be removed, such that a portion of the first channel structure CH may protrude.

A portion from an upper surface of the upper interlayer insulating layer 125 and a portion from an upper end of the first channel dielectric layer CD1 may be removed. This process may be performed by a wet etching process or a dry etching process. Accordingly, a thickness of the upper interlayer insulating layer 125 forming an uppermost portion of the stack structure GS may be reduced, and the upper interlayer insulating layer 125 may be referred to as the interlayer insulating layer 120 after this process.

A portion of the first channel layer 140 and a portion of the first channel pad 149 of the first channel structure CH may protrude to the uppermost interlayer insulating layer 120, and the first channel structure CH may include a protrusion region PR. A height of the protrusion region PR may be varied in example embodiments in a range in which the interlayer insulating layer 120 may stably remain on an uppermost second upper gate electrode 130U2.

Referring to FIG. 10G, a preliminary horizontal insulating layer 150P may be formed, and a plasma treatment may be performed on the preliminary horizontal insulating layer 150P.

The preliminary horizontal insulating layer 150P may be conformally deposited on the entire exposed structure. The preliminary horizontal insulating layer 150P may cover an upper surface of an uppermost interlayer insulating layer 120, an upper surface of the first channel structure CH, and a side surface of the protrusion region PR of the first channel structure CH. The preliminary horizontal insulating layer 150P may include a material different from a material of the interlayer insulating layer 120, such as silicon nitride.

The plasma treatment on the preliminary horizontal insulating layer 150P may be performed in-situ together with the deposition process, but an example embodiment thereof is not limited thereto. By the plasma treatment, properties of the horizontal region deposited horizontally (X-direction or Y-direction), and the vertical region CR deposited vertically (Z-direction) in the preliminary horizontal insulating layer 150P may be different from each other. The vertical region CR may include a region on a side surface of the protrusion region PR of the first channel structure CH.

In the example embodiment of FIGS. 7A and 7B, the vertical region CR may be formed in a different shape in this process. In the example embodiment of FIG. 8, the plasma treatment may be omitted.

Referring to FIG. 10H, the horizontal insulating layer 150 may be formed by removing the vertical region CR of the preliminary horizontal insulating layer 150P.

The vertical region CR may be selectively removed with respect to the horizontal region. The removal process may be performed by, for example, a wet etching process using hydrofluoric acid. Accordingly, the horizontal region of the remaining preliminary horizontal insulating layer 150P may form the horizontal insulating layer 150.

The horizontal insulating layer 150 may be disposed on an uppermost surface of the first channel structure CH, that is, an upper surface of the first channel layer 140 and an upper surface of the first channel pad 149, and on an upper surface of the uppermost interlayer insulating layer 120. The horizontal insulating layer 150 on the uppermost interlayer insulating layer 120 may be horizontally (Y-direction) spaced apart from the protrusion region PR of the first channel structure CH. The horizontal insulating layer 150 may cover a portion of an upper surface of the first channel dielectric layer CD1, but an example embodiment thereof is not limited thereto.

Referring to FIG. 10I, a first cell region insulating layer 192, a first upper gate electrode 130U1, a second separation region US, and a second cell region insulating layer 194 may be formed in order.

The first cell region insulating layer 192 may cover the horizontal insulating layer 150 and the protrusion region PR of the first channel structure CH and may have a flat upper surface. The first upper gate electrode 130U1 may be formed on the first cell region insulating layer 192. The first upper gate electrode 130U1 may be formed as a plurality of electrodes spaced apart from each other in the X-direction by the second separation region US. The first upper gate electrode 130U1 may include a material different from a material of the other gate electrodes 130, but an example embodiment thereof is not limited thereto. For example, the first upper gate electrode 130U1 may include polycrystalline silicon. In some example embodiments, the second separation region US may be formed in a subsequent process rather than in this process.

Referring to FIG. 10J, an upper channel hole SH penetrating or extending through the first upper gate electrode 130U1 may be formed, and a second channel dielectric layer CD2 and a sacrificial spacer layer 117 may be formed.

The upper channel hole SH may be formed to form a second channel structure SCH (see FIG. 3). The upper channel hole SH may be formed to penetrate or extend through the first upper gate electrode 130U1. A portion of the second channel dielectric layer CD2, for example, a second blocking layer 171 and a second charge storage layer 172, may be formed in the upper channel hole SH, and an etch-back process may be performed, such that the upper channel hole SH may extend deeper to expose the horizontal insulating layer 150. In some example embodiments, the upper channel hole SH may be recessed into the horizontal insulating layer 150. In some example embodiments, the etch-back process may be performed after the second tunneling layer 173 is formed.

Thereafter, the second tunneling layer 173 and the sacrificial spacer layer 117 may be formed on the second charge storage layer 172. The sacrificial spacer layer 117 may include a different material from a material of the horizontal insulating layer 150.

In the example embodiments of FIGS. 4A, 4B, and 5, the upper channel hole SH may be formed by further extending downwardly (Z-direction) in this process.

Referring to FIG. 10k, the horizontal insulating layer 150 may be removed from an uppermost surface of the first channel structure CH.

A horizontal expansion portion SH_L may be formed by removing the horizontal insulating layer 150 exposed through a bottom surface of the upper channel hole SH. The horizontal insulating layer 150 may be selectively removed, for example, by a wet etching process. Accordingly, the horizontal insulating layer 150 may remain only on the uppermost interlayer insulating layer 120.

In the example embodiment of FIG. 6, the horizontal insulating layer 150 may partially remain on an outer side of the horizontal expansion portion SH_L in this process and may form an upper-surface insulating layer 155.

Referring to FIG. 10L, the sacrificial spacer layer 117 may be removed, and channel connection portions 160 and second channel structures SCH may be formed.

The sacrificial spacer layer 117 may be removed from each upper channel hole SH, and a second channel layer 170, a second channel buried insulating layer 175, and a second channel pad 179 may be formed, thereby forming second channel structures SCH. Each layer may be formed in the same manner as the first channel structures CH. The material forming the second channel layer 170 may at least partially fill the horizontal expansion portion SH_L and may form the channel connection portion 160. The channel connection portion 160 may be formed together with the second channel layer 170, may include the same material, and may be integrated with the second channel layer 170. The second channel layer 170 may be electrically connected to the first channel pad 149 and the first channel layer 140 of the first channel structure CH through the channel connection portion 160.

Thereafter, referring to FIG. 2 together, by forming studs 180 connected to upper ends of the second channel structures SCH, the semiconductor device 100 may be manufactured.

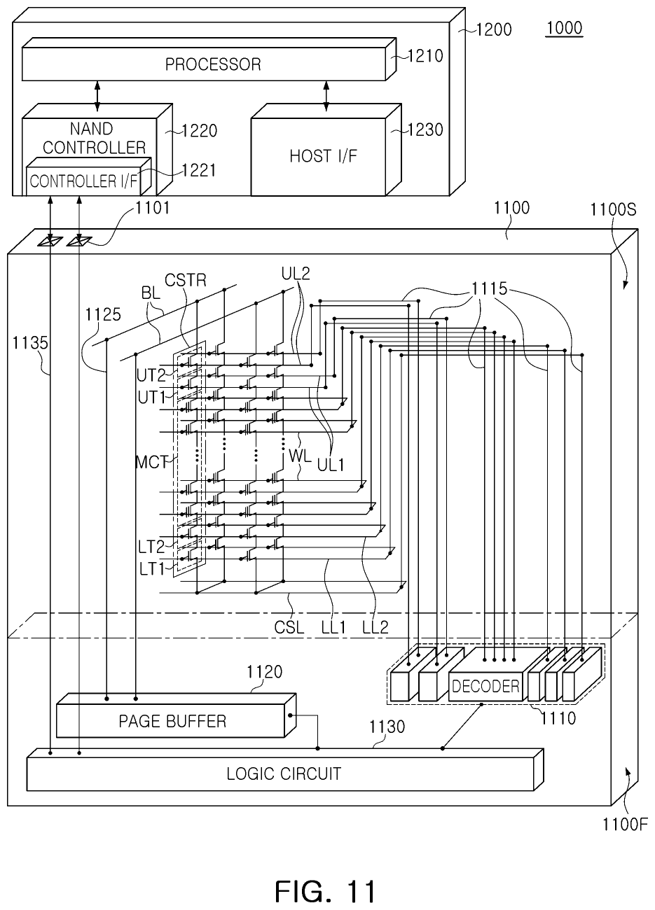

FIG. 11 is a view illustrating a data storage system including a semiconductor device according to an example embodiment.

Referring to FIG. 11, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1, 2, 3A, 3B, 4A, 4B, 5, 6, 7A, 7B, 8 and 9. The semiconductor device 1100 may include a first structure 1100F and a second structure 1100S on the first structure 1100F. In the example embodiments, the first structure 1100F may be disposed on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bitline BL, a common source line CSL, wordlines WL, first and second gate upper lines UL1 and UL2, first and second gate lower lines LL1 and LL2 and memory cell strings CSTR disposed between the bitline BL and the common source line CSL.

In the second structure 1100S, each of the memory cell strings CSTR may include lower transistors LT1 and LT2 adjacent to the common source line CSL, upper transistors UT1 and UT2 adjacent to the bitline BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in the example embodiments.

In the example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

In the example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 or the upper erase control transistor UT2 may be used in an erase operation for erasing data stored in the memory cell transistors MCT using a GIDL phenomenon.

The common source line CSL, the first and second gate lower lines LL1 and LL2, the wordlines WL, and the first and second gate upper lines UL1 and UL2 may be electrically connected to the decoder circuit 1110 through first connection interconnections 1115 extending from the first structure 1100F to the second structure 1100S. The bitlines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In the example embodiments, the data storage system 1000 may include a plurality of semiconductor devices 1100, and in this example, the controller 1200 may control the plurality of semiconductor devices 1100.

The processor 1210 may control overall operation of the data storage system 1000 including the controller 1200. The processor 1210 may operate according to firmware that is executable by the processor, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

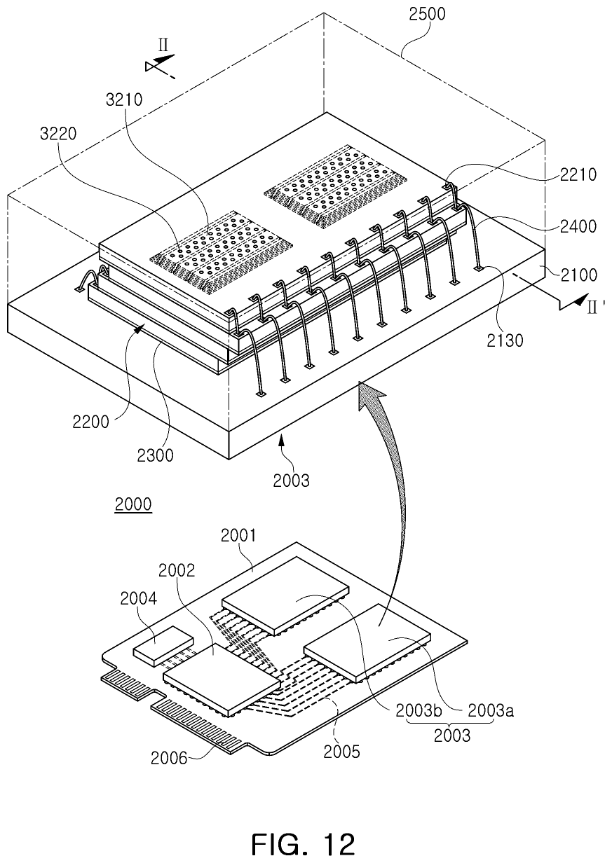

FIG. 12 is a perspective view illustrating a data storage system including a semiconductor device according to an example embodiment.

Referring to FIG. 12 a data storage system 2000 in an example embodiment may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary depending on a communication interface between the data storage system 2000 and the external host. In the example embodiments, the data storage system 2000 may communicate with an external host according to one of a plurality of interfaces, including, for example, universal serial bus (USB), peripheral component interconnect express (PCI-Express), serial advanced technology attachment (SATA), and M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 at least partially covering the semiconductor chips 2200 and the connection structure 2400 on the package substrate 2100.

The package substrate 2100 may be configured as a printed circuit board including upper pads 2130. Each semiconductor chip 2200 may include an input/output pad 2210. The input/output pad 2210 may correspond to the input/output pad 1101 in FIG. 11. Each of the semiconductor chips 2200 may include gate stack structures 3210 and channel structures 3220. Each of the semiconductor chips 2200 may include the semiconductor device described in the aforementioned example embodiment with reference to FIGS. 1, 2, 3A, 3B, 4A, 4B, 5, 6, 7A, 7B, 8, and 9.

In the example embodiments, the connection structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the upper pads 2130 of the package substrate 2100. In the example embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In the example embodiments, the controller 2002 and the semiconductor chips 2200 may be included in a single package. In an example embodiment, the controller 2002 and the semiconductor chips 2200 may be mounted on an interposer substrate different from the main board 2001, and the controller 2002 and the semiconductor chips 2200 may be connected to each other by interconnection formed on the interposer substrate.

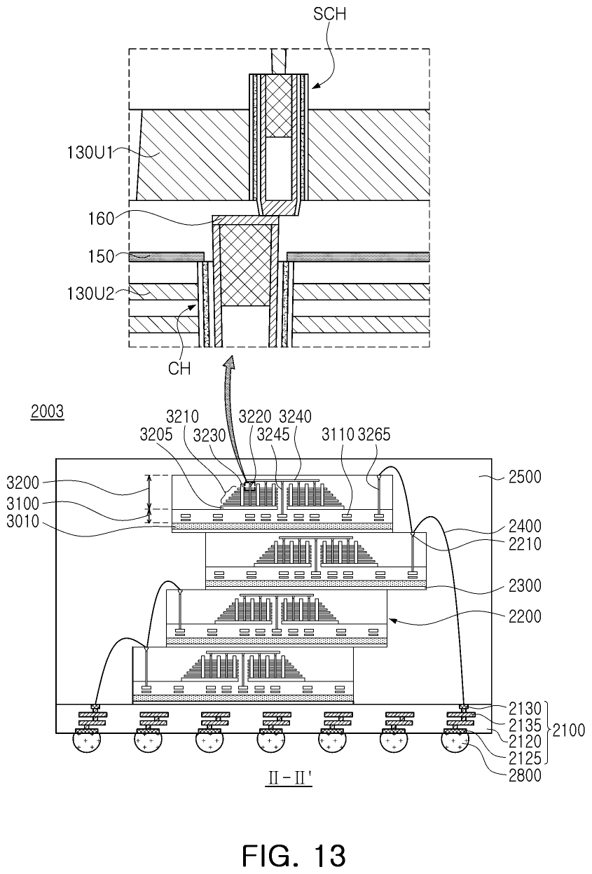

FIG. 13 is a cross-sectional view illustrating a semiconductor package and corresponding to an example embodiment of the semiconductor package 2003 in FIG. 12 taken along line II-II′ according to an example embodiment.

Referring to FIG. 13, in the semiconductor package 2003, the package substrate 2100 may be implemented as a printed circuit substrate. The package substrate 2100 may include a package substrate body portion 2120, upper pads 2130 disposed on an upper surface of the package substrate body portion 2120, lower pads 2125 disposed on the lower surface of the package substrate body 2120 or exposed through the lower surface, and internal interconnections 2135 electrically connecting the upper pads 2130 to the lower pads 2125 in the package substrate body 2120. The upper pads 2130 may be electrically connected to the connecting structures 2400. The lower pads 2125 may be connected to the interconnection patterns 2005 of the main substrate 2001 of the data storage system 2000 through conductive connection portions 2800, as illustrated in FIG. 12.

Each of the semiconductor chips 2200 may include a semiconductor substrate 3010 and a first structure 3100 and a second structure 3200 stacked in order on the semiconductor substrate 3010. The first structure 3100 may include a peripheral circuit region including peripheral interconnections 3110. The second structure 3200 may include a common source line 3205, a gate stack structure 3210 on the common source line 3205, channel structures 3220 penetrating or extending through the gate stack structure 3210, and bitlines 3240 electrically connected to the channel structures 3220. As described in the aforementioned example embodiment with reference to FIGS. 1, 2, 3A, 3B, 4A, 4B, 5, 6, 7A, 7B, 8, and 9, in each of the semiconductor device chips 2200, an upper surface of the horizontal insulating layer 150 may be positioned on a level lower (Z-direction) than an uppermost surface of the first channel structure CH, and the channel connection portion 160 may not expand to an outer side the first channel structure CH and may cover a portion of a lower surface of the second channel structure SCH.

Each of the semiconductor chips 2200 may include a through-interconnection 3245 electrically connected to the peripheral interconnections 3110 of the first structure 3100 and extending into the second structure 3200. The through-interconnection 3245 may be disposed on an external side of the gate stack structure 3210 and may further be disposed to penetrate or extend through the gate stack structure 3210. Each of the semiconductor chips 2200 may further include an input/output pad 2210 (see FIG. 12) electrically connected to the peripheral interconnections 3110 of the first structure 3100.

According to the aforementioned example embodiments, by optimizing or enhancing the structure of the horizontal insulating layer for forming the channel connection portion connecting the first channel structure to the second channel structure, a semiconductor device having improved reliability and a data storage system including the same may be provided.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a first semiconductor device structure including a substrate, circuit devices on the substrate, and circuit interconnection lines on the circuit devices; and
a second semiconductor device structure on the first semiconductor device structure,
wherein the second semiconductor device structure includes:
a plate layer;
gate electrodes including first gate electrodes stacked and spaced apart from each other in a first direction perpendicular to an upper surface of the plate layer on the plate layer and a second gate electrode on the first gate electrodes;
first channel structures extending through the first gate electrodes in the first direction, and each including a first channel layer;
second channel structures extending through the second gate electrode, and each including a second channel layer electrically connected to the first channel layer;
channel connection portions on uppermost surfaces of the first channel structures, and electrically connecting the first channel layers to the second channel layers, respectively; and
a horizontal insulating layer extending between an uppermost first gate electrode among the first gate electrodes and the second gate electrode,
wherein an upper surface of the horizontal insulating layer is on a level lower than a level of the uppermost surfaces of the first channel structures in the first direction where the upper surface of the plate layer provides a base reference plane, and
wherein the horizontal insulating layer is spaced apart from the first channel layer in a second direction perpendicular to the first direction around each of the first channel structures.

2. The semiconductor device of claim 1,
wherein each of the first channel structures includes a first channel dielectric layer, the first channel layer, and a first channel buried insulating layer stacked in order from the first gate electrodes in a channel hole, and further includes a first channel pad forming an upper end, and
wherein the upper surface of the horizontal insulating layer is on a level lower than a level of an upper surface of the first channel pad in the first direction where the upper surface of the plate layer provides the base reference plane.

3. The semiconductor device of claim 2, wherein the upper surface of the horizontal insulating layer is on a level higher than a level of a lower surface of the first channel pad in the first direction where the upper surface of the plate layer provides the base reference plane.

4. The semiconductor device of claim 2, wherein an upper surface of the first channel dielectric layer is positioned on a level lower than a level of the upper surface of the first channel pad in the first direction where the upper surface of the plate layer provides the base reference plane.

5. The semiconductor device of claim 4, wherein the horizontal insulating layer covers a portion of the upper surface of the first channel dielectric layer.

6. The semiconductor device of claim 1, wherein the horizontal insulating layer is spaced apart from the channel connection portions.

7. The semiconductor device of claim 1, wherein each of the channel connection portions is in a region along an outer circumference of the first channel layer on the uppermost surface of each of the first channel structures.

8. The semiconductor device of claim 1, wherein the channel connection portions extend from the uppermost surfaces of the first channel structures along side surfaces of the first channel structures and are in contact with a portion of the side surfaces of the first channel structures.

9. The semiconductor device of claim 1, wherein the second channel structures are shifted from centers of the channel connection portions in the second direction.

10. The semiconductor device of claim 1, wherein the second channel layer covers a portion of a side surface of at least one of the first channel structures.

11. The semiconductor device of claim 1, wherein the second semiconductor device structure further includes an upper-surface insulating layer parallel to the channel connection portion on the uppermost surface of at least one of the first channel structures.

12. The semiconductor device of claim 1, wherein the horizontal insulating layer includes nitride.

13. The semiconductor device of claim 1, wherein the first channel layers, the second channel layers, and the channel connection portions include a same material.

14. A semiconductor device, comprising:
a plate layer;
gate electrodes including first gate electrodes stacked and spaced apart from each other in a first direction perpendicular to an upper surface of the plate layer on the plate layer and a second gate electrode on the first gate electrodes;
a first channel structure extending through the first gate electrodes in the first direction, and including a first channel layer;
a second channel structure extending through the second gate electrode, and including a second channel layer electrically connected to the first channel layer;
a channel connection portion on an uppermost surface of the first channel structure and electrically connecting the first channel layer to the second channel layer; and
a horizontal insulating layer extending between an uppermost first gate electrode among the first gate electrodes and the second gate electrode,
wherein the horizontal insulating layer is on a level different from a level of the channel connection portion in the first direction, and
wherein the channel connection portion covers a portion of a lower surface of the second channel structure and exposes a portion of the lower surface of the second channel structure.

15. The semiconductor device of claim 14, wherein the channel connection portion covers a portion of a lower surface of the second channel layer and exposes a portion of the lower surface of the second channel layer.

16. The semiconductor device of claim 14, wherein an upper surface of the horizontal insulating layer is on a level lower than a level of an upper surface of the channel connection portion in the first direction where the upper surface of the plate layer provides a base reference plane.

17. The semiconductor device of claim 14, wherein an entirety of the channel connection portion overlaps the first channel structure in the first direction.

18. The semiconductor device of claim 14, wherein a lower end of the second channel structure is at a same level as or higher than a level of an upper surface of the horizontal insulating layer in the first direction where the upper surface of the plate layer provides a base reference plane.

19. A data storage system, comprising:
a semiconductor device storage device including a first semiconductor device structure including circuit devices, a second semiconductor device structure on the first semiconductor device structure, and an input/output pad electrically connected to the circuit devices; and
a controller electrically connected to the semiconductor device storage device through the input/output pad and configured to control the semiconductor device storage device, wherein the second semiconductor device structure includes:
a plate layer;
gate electrodes including first gate electrodes stacked and spaced apart from each other in a first direction perpendicular to an upper surface of the plate layer on the plate layer and a second gate electrode on the first gate electrodes;
a first channel structure extending through the first gate electrodes in the first direction, and including a first channel layer;
a second channel structure extending through the second gate electrode, and including a second channel layer electrically connected to the first channel layer;
a channel connection portion on an uppermost surface of the first channel structure and electrically connecting the first channel layer to the second channel layer; and
a horizontal insulating layer extending between an uppermost first gate electrode among the first gate electrodes and the second gate electrode,
wherein an upper surface of the horizontal insulating layer is on a level lower than a level of the uppermost surface of the first channel structure in the first direction where the upper surface of the plate layer provides a base reference plane.

20. The semiconductor device of claim 19, wherein a thickness of the channel connection portion is a same as a thickness of the horizontal insulating layer.
